(19) United States
(12) Patent Application Publication
(10) Pub. No.: US 2020/0335557 A1
(43) Pub. Date: Oct. 22, 2020

(54) ORGANIC LIGHT EMITTING DIODE DISPLAY PIXEL ARRANGEMENT STRUCTURE AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xinjian ZHANG, Wuhan (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/637,800

(22) PCT Filed: Apr. 17, 2019
(86) PCT No.: PCT/CN2019/083116

§ 371 Date: Feb. 10, 2020

(30) Foreign Application Priority Data
Feb. 26, 2019 (CN) 201910140641.X

(51) Int. Cl. H01L 27/32

(52) U.S. Cl. CPC H01L 27/3216; H01L 27/3218

(57) ABSTRACT

Disclosed is an organic light emitting diode display pixel arrangement structure, including a plurality of pixel units; wherein each of the pixel units includes: a ¼ red sub-pixel, a ¼ blue sub-pixel and a ¼ green sub-pixel; an area of the red sub-pixel is equal to an area of the blue sub-pixel and is equal to an area of the green sub-pixel; and the red sub-pixel, the blue sub-pixel and the green sub-pixel are all dodecagons.

### FIELD OF THE INVENTION

The present application relates to a display field, and more particularly to an organic light emitting diode display pixel arrangement structure and a display panel.

### BACKGROUND OF THE INVENTION

As the application of high resolution display devices becomes more widespread, the requirements for the resolution of display devices are also increasing. At present, the purpose of improving the resolution of the display device is generally achieved by reducing the size of the pixels and reducing the spacing among the pixels. However, as the process technology is further refined, the process difficulty and manufacturing cost of the display device will increase. Organic Light-Emitting Diode (OLED) displays are widely considered as the focus of next generation display technology because of the good properties of high brightness, fast response, low power consumption and flexibility. Compared with thin film transistor liquid crystal displays, OLED displays possess the biggest advantages of being ultra-thin, transparent and flexible. At present, OLED displays are still prepared by vapor deposition technology, and fine metal masks (FMM) are required for preparing pixels using vapor deposition technology. Therefore, the pixel design and arrangement of the fine metal mask is a prerequisite for determining the high resolution of the screen.

In the current display panel technology, the pixel arrangement possesses many advantages, such as higher brightness and lower cost under the same brightness. Meanwhile, the shortcomings of this technology cannot be ignored, such as showing some fine content, the clarity will be greatly reduced, resulting in that small fonts cannot be clearly displayed; For compensating for the color problem, when the color division area is displayed under this pixel technology, the dividing line will generate a grid-like spot, which is twice of the actual pixel pitch. Therefore, the display of this pixel technology must possess a sufficiently high resolution to compensate for the reduction in visual effects due to the texture with double pixel pitch.

In conclusion, in the pixel arrangement technology according to the prior art, the problem that the high-resolution display generates a grid-like spot, which is twice of the actual pixel pitch and the problem that color mixing is easy to occur due to the close distance among the pixels of different colors. Thus, there is an urgent need for improvement.

The present application relates to a pixel arrangement structure and a display panel for solving the problem that the high-resolution display generates a grid-like spot, which is twice of the actual pixel pitch and the problem that color mixing is easy to occur due to the close distance among the pixels of different colors.

### SUMMARY OF THE INVENTION

To solve the aforesaid problem, the technical solution of the present application is described as follows:

the present application provides an organic light emitting diode display pixel arrangement structure, including a plurality of pixel units; wherein each of the pixel units includes: a ¼ red sub-pixel, a ¼ blue sub-pixel and a ¼ green sub-pixel; an area of the red sub-pixel is equal to an area of the blue sub-pixel and is equal to an area of the green sub-pixel; and the red sub-pixel, the blue sub-pixel and the green sub-pixel are all dodecagons; wherein the dodecagon are set in a regular octagon, and an upper end, a lower end, a left end and a right end of the dodecagon are equal to any side of the regular octagon.

According to one preferred embodiment provided by the present application, eight sides of the red sub-pixel, the blue sub-pixel and the green sub-pixel constitute four concave triangles.

According to one preferred embodiment provided by the present application, the concave triangles are isosceles triangles.

According to one preferred embodiment provided by the present application, the red sub-pixels are arranged at 180 degrees centering on the green sub-pixel, and the blue sub-pixels are arranged at 180 degrees centering on the green sub-pixel, and the red sub-pixels and the blue sub-pixels are disposed in a same row or in a same column, and are located on one side of the green sub-pixel.

According to one preferred embodiment provided by the present application, a distance between the green sub-pixel and the red sub-pixel is equal to a distance between the green sub-pixel and the blue sub-pixel.

According to one preferred embodiment provided by the present application, no common side exists between the red sub-pixel and the green sub-pixel which are adjacent and between the blue sub-pixel and the green sub-pixel which are adjacent.

According to one preferred embodiment provided by the present application, two common points exist among the red sub-pixel, the blue sub-pixel and the green sub-pixel.

According to one preferred embodiment provided by the present application, a distance between the red sub-pixel and the blue sub-pixel, which are adjacent, is equal to or greater than a length of one side of the green sub-pixel.

According to one preferred embodiment provided by the present application, every two of the red sub-pixels and every two of the blue sub-pixels surround one of the green sub-pixels.

The present application further provides an organic light emitting diode display pixel arrangement structure, including a plurality of pixel units; wherein each of the pixel units includes: a ¼ red sub-pixel, a ¼ blue sub-pixel and a ¼ green sub-pixel; an area of the red sub-pixel is equal to an area of the blue sub-pixel and is equal to an area of the green sub-pixel; and the red sub-pixel, the blue sub-pixel and the green sub-pixel are all dodecagons.

According to one preferred embodiment provided by the present application, eight sides of the red sub-pixel, the blue sub-pixel and the green sub-pixel constitute four concave triangles.

According to one preferred embodiment provided by the present application, the concave triangles are isosceles triangles.

According to one preferred embodiment provided by the present application, the red sub-pixels are arranged at 180 degrees centering on the green sub-pixel, and the blue sub-pixels are arranged at 180 degrees centering on the green sub-pixel, and the red sub-pixels and the blue sub-pixels are disposed in a same row or in a same column, and are located on one side of the green sub-pixel.

According to one preferred embodiment provided by the present application, a distance between the green sub-pixel and the red sub-pixel is equal to a distance between the green sub-pixel and the blue sub-pixel.

According to one preferred embodiment provided by the present application, no common side exists between the red sub-pixel and the green sub-pixel which are adjacent and between the blue sub-pixel and the green sub-pixel which are adjacent.

According to one preferred embodiment provided by the present application, a distance between the red sub-pixel and the blue sub-pixel, which are adjacent, is equal to or greater than a length of one side of the green sub-pixel.

According to one preferred embodiment provided by the present application, every two of the red sub-pixels and every two of the blue sub-pixels surround one of the green sub-pixels.

The present application further provides an organic light emitting diode display pixel arrangement structure, including a plurality of pixel units; wherein each of the pixel units includes: a ¼ red sub-pixel, a ¼ blue sub-pixel and a ¼ green sub-pixel; an area of the red sub-pixel is equal to an area of the blue sub-pixel and is equal to an area of the green sub-pixel; and the red sub-pixel, the blue sub-pixel and the green sub-pixel are all octagons, wherein four of the eight sides are arc-shaped.

Compared with the prior art, the present invention provides an organic light emitting diode display pixel arrangement structure. By sharing sub-pixels for adjacent pixels, the number of sub-pixels is reduced, and the effect of simulating high resolution with low resolution is achieved. Then, the respective sub-pixels are all dodecagons, wherein eight of the twelve sides appear concave triangles, and only two common points exist between two intersected sub-pixels to reduce the problem of poor color mixing caused due to that the vapor deposition shadow is larger than the design size in the vapor deposition.

### BRIEF DESCRIPTION OF THE DRAWINGS

In order to more clearly illustrate the embodiments of the present application, the following figures will be described in the embodiments are briefly introduced. It is obvious that the drawings are only some embodiments of the present application, those of ordinary skill in this field can obtain other figures according to these figures without paying the premise.

FIG. 1 is a first structural diagram of an organic light emitting diode display pixel arrangement structure according to an embodiment of the present application.

FIG. 2 is a second structural diagram of an organic light emitting diode display pixel arrangement structure according to an embodiment of the present application.

FIG. 3 is a first structural diagram of a sub pixel of an organic light emitting diode display pixel arrangement structure according to an embodiment of the present application.

FIG. 4 is a second structural diagram of a sub pixel of an organic light emitting diode display pixel arrangement structure according to an embodiment of the present application.

FIG. 5 is a first vapor deposition mask diagram of an organic light emitting diode display pixel arrangement structure according to an embodiment of the present application.

FIG. 6 is a second vapor deposition mask diagram of an organic light emitting diode display pixel arrangement structure according to an embodiment of the present application.

### DETAILED DESCRIPTION OF PREFERRED EMBODIMENTS

For better explaining the technical solution and the effect of the present invention, the present invention will be further described in detail with the accompanying drawings in the specific embodiments. It is clear that the described embodiments are merely part of embodiments of the present application, but not all embodiments. Based on the embodiments of the present application, all other embodiments to those of skilled in the premise of no creative efforts obtained, should be considered within the scope of protection of the present application.

In the description of the present application, it is to be understood that the terms “center”, “longitudinal”, “transverse”, “length”, “width”, “thickness”, “upper”, “lower”, “front”, “Orientation of “post”, “left”, “right”, “vertical”, “horizontal”, “top”, “bottom”, “inside”, “outside”, “clockwise”, “counterclockwise”, etc. are positional relationships based on the orientations or positional relationships shown in the drawings, and are merely for the convenience of the description of the present application and the simplified description, and do not indicate or imply that the device or component referred to have specific orientations, and are constructed and operated in specific orientations. Therefore, these should not be construed as limiting the present application. Moreover, the terms “first” and “second” are used for descriptive purposes only and are not to be construed as indicating or implying a relative importance or implicitly indicating the number of indicated technical features. Thus, features defining “first” and “second” may include one or more of the features with either explicitly or implicitly. In the description of the present application, “plurality” means two or more unless with being specifically indicated otherwise.

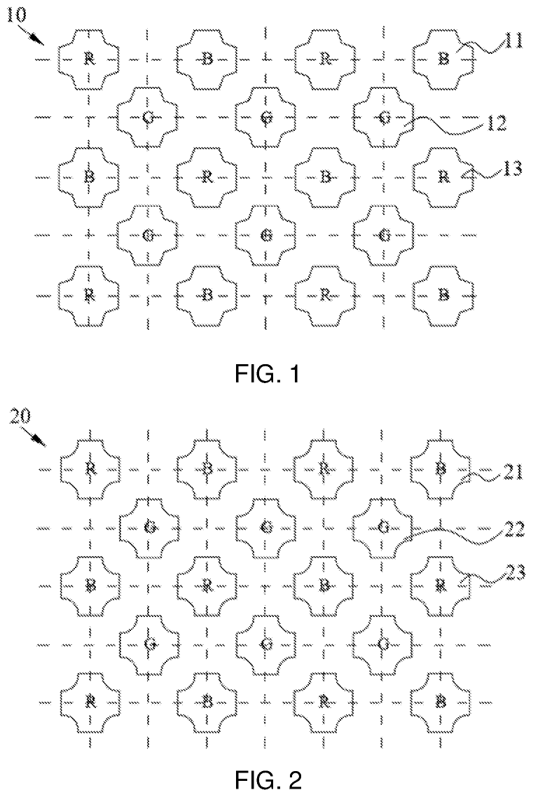

Please refer to FIG. 1, which is a first structural diagram of an organic light emitting diode display pixel arrangement structure 10.The blue sub-pixel 11, the green sub-pixel 12 and the red sub-pixel 13 are all dodecagons.

Please refer to FIG. 2, which is a second structural diagram of an organic light emitting diode display pixel arrangement structure. The blue sub-pixel 21, the green sub-pixel 22 and the red sub-pixel 23 are all octagons, wherein four of the eight sides of each sub-pixel are arc-shaped.

Embodiment one

The present application provides an organic light emitting diode display pixel arrangement structure 10, including a plurality of pixel units; wherein each of the pixel units includes: a ¼ red sub-pixel 13, a ¼ blue sub-pixel 11 and a ¼ green sub-pixel 12; an area of the red sub-pixel 13 is equal to an area of the blue sub-pixel 11 and is equal to an area of the green sub-pixel 12; and the red sub-pixel 13, the blue sub-pixel 11 and the green sub-pixel 12 are all dodecagons.

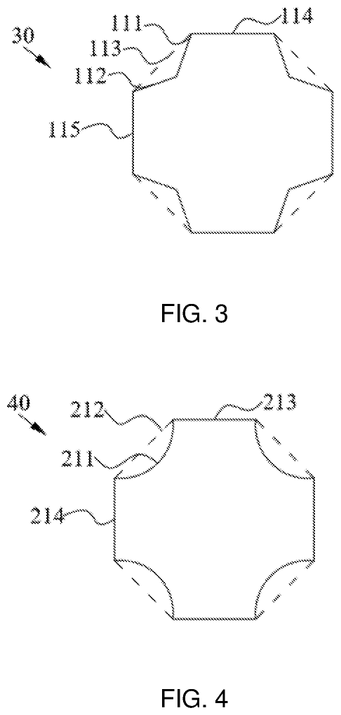

According to one preferred embodiment provided by the present application, eight sides of the red sub-pixel 13, the blue sub-pixel 11 and the green sub-pixel 12 constitute four concave triangles. Please refer to FIG. 3. One sub-pixel includes twelve sides. The upper end 114, the lower end, the left end 115, the right end and the four virtual sides may form a regular octagon. Namely, the upper end 114 and the left end 115 have the same length. The lengths of the respective concave sides are equal, that is, the concave first side 111 and the concave second side 112 are equal in length. The concave first side 111, the concave second side 112 and the virtual side 113 together form a concave triangle. Each sub-pixel includes four concave triangles.

According to one preferred embodiment provided by the present application, the concave triangles are isosceles triangles. The length of the two waists of the isosceles triangle can be variable according to actual needs.

According to one preferred embodiment provided by the present application, the red sub-pixels 13 are arranged at 180 degrees centering on the green sub-pixel 12, and the blue sub-pixels 11 are arranged at 180 degrees centering on the green sub-pixel 12, and the red sub-pixels 13 and the blue sub-pixels 11 are disposed in a same row or in a same column, and are located on one side of the green sub-pixel 12.

According to one preferred embodiment provided by the present application, a distance between the green sub-pixel 12 and the red sub-pixel 13 is equal to a distance between the green sub-pixel 12 and the blue sub-pixel 11.

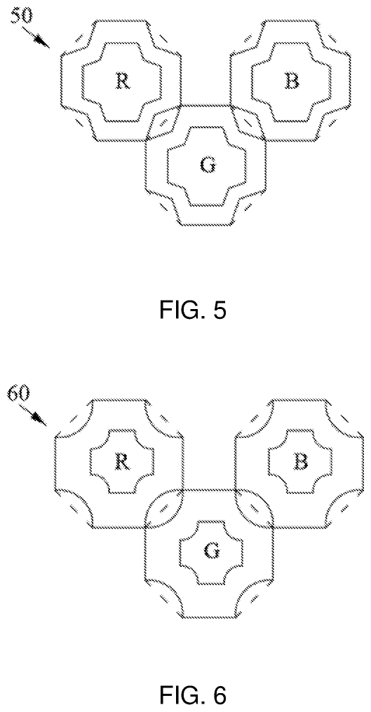

According to one preferred embodiment provided by the present application, no common side exists between the red sub-pixel 13 and the green sub-pixel 12 which are adjacent and between the blue sub-pixel 11 and the green sub-pixel 12 which are adjacent. Please refer to FIG. 5. As implementing vapor deposition, although the size of the opening after evaporation is larger than the design size, the area of the shadow of the mask among adjacent pixels may be overlapped to extend at most with the radius of the intersection point. The intersection of the two triangles is blank. The overlapped area of the shadow of the mask is much smaller than the condition of the pixel arrangement that the edges are overlapped, which greatly reduces the possibility of pixel color mixing.

According to one preferred embodiment provided by the present application, a distance between the red sub-pixel 13 and the blue sub-pixel 11, which are adjacent, is equal to or greater than a length of one side 114 of the green sub-pixel 12.

According to one preferred embodiment provided by the present application, every two of the red sub-pixels 13 and every two of the blue sub-pixels 11 surround one of the green sub-pixels 12. Namely, every two pixel units share one green sub-pixel 12, which reduces a number of sub-pixels and also achieves the effect of simulating high resolution with low resolution.

The present application further provides a display panel including: a substrate and a pixel arrangement structure disposed on the substrate, wherein the pixel arrangement structure includes the organic light emitting diode display pixel arrangement structure according to any one of the above.

Embodiment two

The present application provides an organic light emitting diode display pixel arrangement structure 20, including a plurality of pixel units; wherein each of the pixel units includes: a ¼ red sub-pixel 23, a ¼ blue sub-pixel 21 and a ¼ green sub-pixel 22; an area of the red sub-pixel 23 is equal to an area of the blue sub-pixel 21 and is equal to an area of the green sub-pixel 22; and the red sub-pixel 23, the blue sub-pixel 21 and the green sub-pixel 22 are all octagons, wherein four of the eight sides are arc-shaped.

According to one preferred embodiment provided by the present application, eight sides of the red sub-pixel 23, the blue sub-pixel 21 and the green sub-pixel 22 constitute four concave crescent shapes. Please refer to FIG. 4. One sub-pixel includes eight sides. The upper end 213, the lower end, the left end 214, the right end and the four virtual sides may form a regular octagon. Namely, the upper end 213 and the left end 214 have the same length. The lengths of the respective concave sides are equal. The concave first side 211 and the virtual side 212 together form a concave crescent shape. Each sub-pixel includes four concave crescent shapes.

According to one preferred embodiment provided by the present application, the red sub-pixels 23 are arranged at 180 degrees centering on the green sub-pixel 22, and the blue sub-pixels 21 are arranged at 180 degrees centering on the green sub-pixel 22, and the red sub-pixels 23 and the blue sub-pixels 21 are disposed in a same row or in a same column, and are located on one side of the green sub-pixel 22.

According to one preferred embodiment provided by the present application, a distance between the green sub-pixel 22 and the red sub-pixel 23 is equal to a distance between the green sub-pixel 22 and the blue sub-pixel 21.

According to one preferred embodiment provided by the present application, no common side exists between the red sub-pixel 23 and the green sub-pixel 22 which are adjacent and between the blue sub-pixel 21 and the green sub-pixel 22 which are adjacent. Please refer to FIG. 6. As implementing vapor deposition, although the size of the opening after evaporation is larger than the design size, the area of the shadow of the mask among adjacent pixels may be overlapped to extend at most with the radius of the intersection point. The intersection of the two crescent shapes is blank. The overlapped area of the shadow of the mask is much smaller than the condition of the pixel arrangement that the edges are overlapped, which greatly reduces the possibility of pixel color mixing.

According to one preferred embodiment provided by the present application, a distance between the red sub-pixel 23 and the blue sub-pixel 21, which are adjacent, is equal to or greater than a length of one side 213 of the green sub-pixel 22.

According to one preferred embodiment provided by the present application, every two of the red sub-pixels 23 and every two of the blue sub-pixels 21 surround one of the green sub-pixels 22. Namely, every two pixel units share one green sub-pixel 22, which reduces a number of sub-pixels and also achieves the effect of simulating high resolution with low resolution.

The present application further provides a display panel including: a substrate and a pixel arrangement structure disposed on the substrate, wherein the pixel arrangement structure includes the organic light emitting diode display pixel arrangement structure according to any one of the above.

The organic light emitting diode display pixel arrangement structure and the display panel provided by the embodiments of the present application are described in detail as aforementioned, and the principles and implementations of the present application have been described with reference to specific illustrations. The description of the foregoing embodiments is merely for helping to understand the technical solutions of the present application and the core ideas thereof; those skilled in the art should understand that the technical solutions described in the foregoing embodiments may be modified, or some of the technical features may be equivalently replaced; and the modifications or replacements do not deviate from the spirit and scope of the technical solutions of the embodiments of the present application.

What is claimed is:

1. An organic light emitting diode display pixel arrangement structure, including a plurality of pixel units; wherein each of the pixel units includes: a ¼ red sub-pixel, a ¼ blue sub-pixel and a ¼ green sub-pixel; an area of the red sub-pixel is equal to an area of the blue sub-pixel and is equal to an area of the green sub-pixel; and
the red sub-pixel, the blue sub-pixel and the green sub-pixel are all dodecagons;
wherein the dodecagon are set in a regular octagon, and an upper end, a lower end, a left end and a right end of the dodecagon are equal to any side of the regular octagon.

2. The organic light emitting diode display pixel arrangement structure according to claim 1, wherein eight sides of the red sub-pixel, the blue sub-pixel and the green sub-pixel constitute four concave triangles.

3. The organic light emitting diode display pixel arrangement structure according to claim 2, wherein the concave triangles are isosceles triangles.

4. The organic light emitting diode display pixel arrangement structure according to claim 3, wherein the red sub-pixels are arranged at 180 degrees centering on the green sub-pixel, and the blue sub-pixels are arranged at 180 degrees centering on the green sub-pixel, and the red sub-pixels and the blue sub-pixels are disposed in a same row or in a same column, and are located on one side of the green sub-pixel.

5. The organic light emitting diode display pixel arrangement structure according to claim 4, wherein a distance between the green sub-pixel and the red sub-pixel is equal to a distance between the green sub-pixel and the blue sub-pixel.

6. The organic light emitting diode display pixel arrangement structure according to claim 5, wherein no common side exists between the red sub-pixel and the green sub-pixel which are adjacent and between the blue sub-pixel and the green sub-pixel which are adjacent.

7. The organic light emitting diode display pixel arrangement structure according to claim 6, wherein two common points exist among the red sub-pixel, the blue sub-pixel and the green sub-pixel.

8. The organic light emitting diode display pixel arrangement structure according to claim 6, wherein a distance between the red sub-pixel and the blue sub-pixel, which are adjacent, is equal to or greater than a length of one side of the green sub-pixel.

9. The organic light emitting diode display pixel arrangement structure according to claim 1, wherein every two of the red sub-pixels and every two of the blue sub-pixels surround one of the green sub-pixels.

10. An organic light emitting diode display pixel arrangement structure, including a plurality of pixel units; wherein each of the pixel units includes: a ¼ red sub-pixel, a ¼ blue sub-pixel and a ¼ green sub-pixel; an area of the red sub-pixel is equal to an area of the blue sub-pixel and is equal to an area of the green sub-pixel; and
the red sub-pixel, the blue sub-pixel and the green sub-pixel are all dodecagons.

11. The organic light emitting diode display pixel arrangement structure according to claim 10, wherein eight sides of the red sub-pixel, the blue sub-pixel and the green sub-pixel constitute four concave triangles.

12. The organic light emitting diode display pixel arrangement structure according to claim 11, wherein the concave triangles are isosceles triangles.

13. The organic light emitting diode display pixel arrangement structure according to claim 12, wherein the red sub-pixels are arranged at 180 degrees centering on the green sub-pixel, and the blue sub-pixels are arranged at 180 degrees centering on the green sub-pixel, and the red sub-pixels and the blue sub-pixels are disposed in a same row or in a same column, and are located on one side of the green sub-pixel.

14. The organic light emitting diode display pixel arrangement structure according to claim 13, wherein a distance between the green sub-pixel and the red sub-pixel is equal to a distance between the green sub-pixel and the blue sub-pixel.

15. The organic light emitting diode display pixel arrangement structure according to claim 14, wherein no common side exists between the red sub-pixel and the green sub-pixel which are adjacent and between the blue sub-pixel and the green sub-pixel which are adjacent.

16. The organic light emitting diode display pixel arrangement structure according to claim 14, wherein a distance between the red sub-pixel and the blue sub-pixel, which are adjacent, is equal to or greater than a length of one side of the green sub-pixel.

17. The organic light emitting diode display pixel arrangement structure according to claim 10, wherein every two of the red sub-pixels and every two of the blue sub-pixels surround one of the green sub-pixels.

18. An organic light emitting diode display pixel arrangement structure, including a plurality of pixel units; wherein each of the pixel units includes: a ¼ red sub-pixel, a ¼ blue sub-pixel and a ¼ green sub-pixel; an area of the red sub-pixel is equal to an area of the blue sub-pixel and is equal to an area of the green sub-pixel; and the red sub-pixel, the blue sub-pixel and the green sub-pixel are all octagons, wherein four of the eight sides are arc-shaped.
